(19) United States
(12) Patent Application Publication
(10) Pub. No.: US 2025/0349535 A1
(43) Pub. Date: Nov. 13, 2025

(54) Semiconductor Device Having Dielectric Material Treated with Microwave Plasma and Method of Fabricating Thereof

(71) Applicant: Taiwan Semiconductor Manufacturing Company, Ltd., Hsin-Chu (TW)

(72) Inventors: Szu-Hua CHEN, Tainan City (TW); Lilin CHANG, Taipei City (TW); Yahru CHENG, Taipei (TW); Wei-Yen WOON, Taoyuan City (TW); Szuya LIAO, Zhubei (TW)

(21) Appl. No.: 19/278,028

(22) Filed: Jul. 23, 2025

Related U.S. Application Data
(63) Continuation of application No. 18/498,900, filed on Oct. 31, 2023.

(51) Int. Cl. H01L 21/02; H01J 37/32; H01L 21/768; H01L 23/532; H10D 84/03; H10D 88/00

(52) U.S. Cl. CPC H01L 21/0234; H01L 21/02282; H01L 21/76826; H01L 23/5329; H10D 84/038; H10D 88/01; H01J 37/32192; H01L 21/02126; H01L 21/02164; H01L 21/02167; H01L 21/0217

(57) ABSTRACT

A low thermal budget dielectric material deposition process is provided. The dielectric material may be deposited using spin-on coating, and treated with a microwave plasma treatment. In some implementations, the dielectric material is used adjacent a contact feature of a CFET device, such as a contact feature providing connection to a source/drain region of a bottom transistor of a CFET device.

### CROSS-REFERENCE TO RELATED APPLICATIONS

This application is a continuation of U.S. patent application Ser. No. 18/498,900 filed Oct. 31, 2023, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, semiconductor fabrication inevitably involves depositing a dielectric material. In some instances this dielectric material is deposited in high-aspect ratio regions. And in some instances, this dielectric material must be etched back or planarized after deposition. An increase in a quality of the dielectric material is desired for performance of the device and also for the uniformity of subsequent processing. While methods of forming dielectric materials have been suitable in some respects, improvement in dielectric quality and/or ease of formation is desired.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow diagram of an embodiment of a method of forming a dielectric material, according to one or more aspects of the present disclosure.

FIG. 2 illustrates a fragmentary top view of a complementary field effect transistor (CFET) 200 having a gate-all-around structure, according to one or more aspects of the present disclosure.

FIGS. 3-18 each illustrate a fragmentary cross-sectional view of the device 200 along various cross-sectional cut lines, according to one or more aspects of the present disclosure.

FIGS. 19-26 illustrates a fragmentary cross-sectional view of another device 2300, according to one or more aspects of the present disclosure.

FIG. 27 illustrates a fragmentary cross-sectional view of a device 3100, according to one or more aspects of the present disclosure.

FIGS. 28 and 29 illustrate a chemical structure of an embodiment of a dielectric material before and after a plasma treatment according to aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Dielectric materials are used in various isolation features in semiconductor devices. One semiconductor device that typically implements dielectric materials are stacked multi-gate devices where a top multi-gate device is disposed over a bottom multi-gate device. When the top multi-gate device and the bottom multi-gate device are of different conductivity types, the stacked multi-gate device may be a complementary field effect transistor (CFET). Formation of some dielectric isolation features in a stacked multi-gate device may come after formation of metal gates or metal interconnects.

After depositing a dielectric material, some processes may implement an anneal process to improve the quality and/or density of the dielectric material. The anneal may be performed at an elevated temperature. The anneal processing, including the exposure to high temperatures, can introduce risk to performance or integrity of other components of the device such as metal gate structures and metal lines. In some instances, the annealing may cause undesired threshold voltage shifting or on-state current degradation. Thus, there may processes and devices that may benefit from dielectric materials formed in methods that provide the dielectric material with a low-thermal-budget.

The present disclosure provides methods of forming dielectric materials applied to semiconductor devices such as CFETs. However, the disclosure is not so limited. A person of skill in the art would recognize aspects of the present disclosure also apply to the formation of dielectric materials in other device types.

In an example process, the dielectric material is deposited by spin-on deposition. After spin-on deposition, a microwave treatment process is performed. These steps can be performed at a low process temperature, reducing a risk to existing structures, including metal gate structures. Further, the methods form a dielectric layer that has uniform quality (e.g., without seams) and high density.

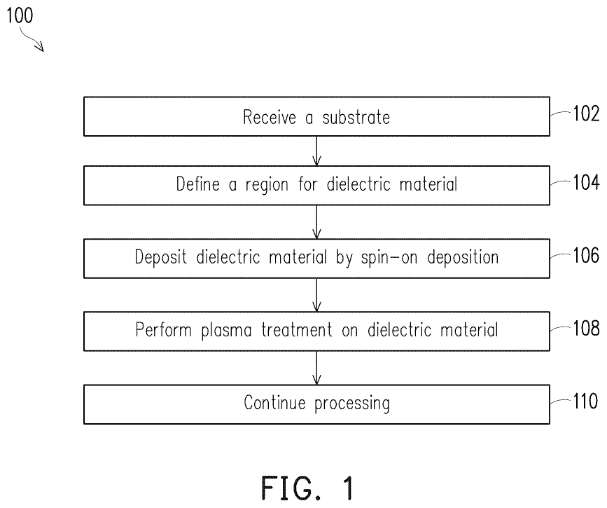

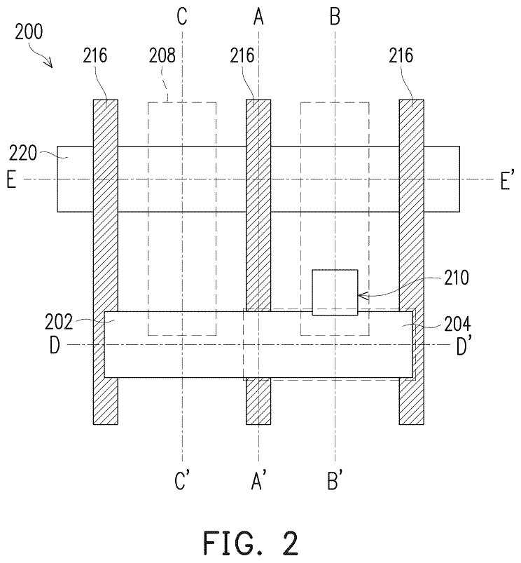

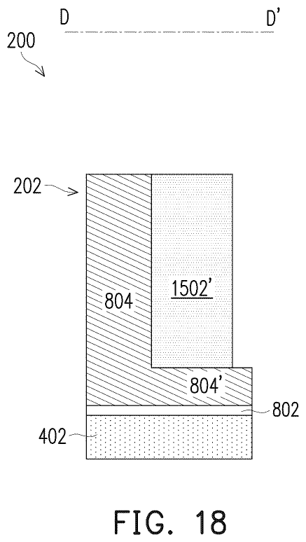

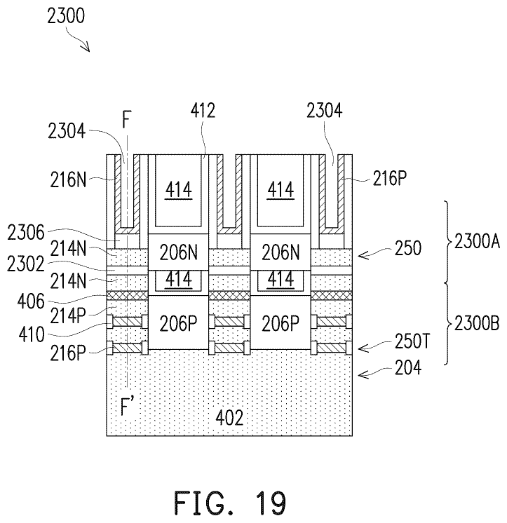

FIG. 1 is a flowchart illustrating a method 100 for forming a dielectric layer. Method 100 is merely an example and is not intended to limit the present disclosure to what is explicitly illustrated in method 100. Additional steps may be provided before, during and after method 100, and some steps described can be replaced, eliminated, or moved around for additional embodiments of the method. Not all steps are described herein in detail for reasons of simplicity. Method 100 may be applied in processes depicted in FIGS. 2-27, which are fragmentary perspective, cross-sectional or top views of a device 200, a device 2300, or a device 3100 at different stages of fabrication. It is noted that while the device 200, device 2300 and device 3100 include some different reference numerals, they may be the same workpiece or different regions of the same workpiece. Additionally, throughout the present application, like reference numerals denote like features, unless otherwise excepted.

Method 100 includes block 102, where a substrate is provided. The substrate may include an elementary (single element) semiconductor, such as silicon (Si), germanium (Ge), and/or other suitable materials; a compound semiconductor (i.e., alloy semiconductor), such as silicon carbide (SiC), gallium arsenic (GaAs), gallium phosphide (GaP), indium phosphide (InP), indium arsenide (InAs), indium antimonide (InSb), silicon germanium (SiGe), gallium arsenic phosphide (GaAsP), aluminum indium arsenide (AlInAs), aluminum gallium arsenide (AlGaAs), gallium indium arsenide (GaInAs), gallium indium arsenide phosphide (GaInP), gallium indium phosphide (GaInAsP), and/or other suitable materials. The substrate may be a single-layer material having a uniform composition. Alternatively, the substrate may include multiple material layers having similar or different compositions suitable for IC device manufacturing. In one example, the substrate may be a silicon-on-insulator (SOI) substrate having a silicon layer formed on a buried silicon oxide (BOX) layer. In some embodiments, the substrate includes various doped regions, such as n-type wells or p-type wells. The doped regions may be doped with n-type dopants, such as phosphorus (P) or arsenic (As), and/or p-type dopants, such as boron (B) or BF₂, depending on design requirements. Doped regions may be formed by implantation of dopant atoms, in-situ doped epitaxial growth, and/or other suitable techniques.

The substrate of block 102 may include various semiconductor devices or portions thereof at various stages of fabrication. Some features that have already been formed in whole or in part on the substrate may include, for example, active regions, dielectric isolation features, metal gate structures, dielectric gate spacers, contact structures, epitaxial source/drain features, contact structures, and/or other features. In an implementation, at least one metal feature (e.g., a metal gate structure) is provided on the substrate prior to performing blocks 106 and 108 of the method 100 discussed below.

At block 104, a region where dielectric material is to be deposited is defined or prepared. The region may have an aspect ratio (height:width) that is greater than 1:1. In an embodiment, the region may have an aspect ratio greater than 4. In some implementations, the region may be between metal lines or vias, such as between contact elements. In some implementations, the region may be adjacent other conductive features such as gate structures or source/drain features.

At block 106 of the method 100, a dielectric layer is deposited over the substrate and within the region defined in block 104. In an embodiment, the dielectric layer includes a dielectric material including silicon (Si) and oxygen (O). The dielectric layer may also include additional elements, such as carbon (C) and/or hydrogen (H).

Exemplary dielectric materials used to form the dielectric layer include the following in Table 1:

| Compound | | |
|---|---|---|
| 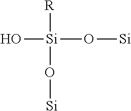 | where R is —CH3, —C2H5, or other alkyl series for example with a carbon number between 1 and 10, or R is —OH | |
| 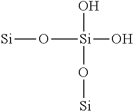 | | |
| 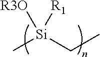 | where R1 and R3 are each one of —CH3, —C2H5, or other alkyl series for example | where n is between approximately 10 and approximately 20 |
| | with a carbone number | |
| | between 1 and 10 | |
| 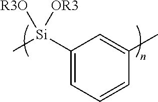 | where each R1, R2, R3 is one of —CH3, —C2H5, or other alkyl series for example with a carbone number between 1 and 10 | where n is between approximately 10 and approximately 20 |
| 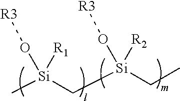 | where each R3 is one of —CH3, —C2H5, or other alkyl series for example with a carbon number between 1 and 10 | where the ratio of “l” to “m” is between approximately 0.5 to approximately 0.95 |

or combinations thereof. In some implementations, two, three, four or more of the materials in Table 1 may be provided together to form a dielectric material deposited in block 106. In an embodiment, the dielectric materials of Table 1 are present in a material prepared for deposition and/or provided as deposited (e.g., by spin-on deposition). However, after deposition, the dielectric material may, in some embodiments, become SiO or SiOC with varying compositions, including SiOC where the atomic percentage of carbon is greater than 0% and less than 30%. In an embodiment, the atomic percentage of carbon is provided after a baking process.

The deposition of block 106 may be performed by a spin-on deposition process also referred to as a spin coating. The spin-on deposition process may include a first step of deposition of the dielectric material, such as discussed above. In some implementations, the dielectric material is accompanied with a solvent, which is subsequently evaporated. The spin-on deposition then includes a spin-up to a desired spin speed, and a spin off. The spin-on deposition further includes evaporation of the solvent. The spin-on deposition may be performed at a velocity between approximately 1000 and 8000 revolutions per minute (rpm). The spin-on deposition may be performed for approximately 30 seconds to approximately 60 seconds. In an embodiment, the spin-on deposition is performed at approximately room temperature. In some implementations, a soft bake process is performed after spin-on coating. The soft bake may be a low temperature bake at for example approximately 100° C. or less. Other drying processes may also be implemented.

In an embodiment, the spin-on coating deposition allows for filling the dielectric region of block 104 with a dielectric material without a seam forming in the dielectric region. Rather, the dielectric material is filled uniformly and/or in a bottom-up manner in the dielectric region (e.g., within a trench).

In an embodiment, the deposition is provided at a temperature of between approximately 120° C. and 250° C. In some implementations, the deposition is spin-on deposition as discussed above and the temperature is selected based in part on the solvent evaporation requirements. Thus, using spin-on deposition allows for a relatively low impact to the thermal budget.

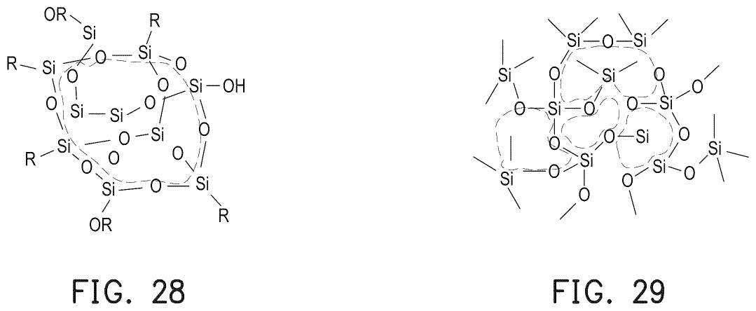

The method 100 then proceeds to block 108 where a treatment is performed on dielectric material. In an embodiment, the treatment is a microwave (MW) plasma. The MW plasma treatment may serve to reconstruct the dielectric material. In an embodiment, the reconstruction prepares an amorphous network. In some embodiments, the reconstruction forms certain bonds (e.g., O—Si—O). In an embodiment, the MW plasma treatment may serve to densify the dielectric material. The densification may increase the grams per cm³ of the dielectric layer. The MW plasma treatment may also remove impurities. Block 108 provides the MW plasma treatment with high plasma density and low ion energy to in some implementations provide one or more the features previously discussed. FIG. 28 illustrates the dielectric material after deposition. FIG. 29 illustrates the dielectric material after plasma treatment.

In an embodiment, block 108 treatment includes a MW plasma using an inert gas such as helium, argon or other suitable gas. In an embodiment, block 108 treatment includes a MW frequency having radiation centered around approximately 2.45 GHz. In an embodiment, block 108 includes a MW plasma is performed at a temperature between approximately 300° C. to approximately 500° C. In an embodiment, the MW plasma treatment is performed at a temperature of less than approximately 500° C. Thus, in some implementation, the thermal impact to the device does not extend above 500° C.; that is, the structures (e.g., metal gates and/or other metal features) are not exposed to a temperature greater than 500° C. In an embodiment, the impact to a thermal budget for block 108 (and block 106) is less than approximately 450° C. In an embodiment, block 108 has a MW plasma performed at a source power between approximately 1000 Watts (W) to approximately 4000 W. In some implementations, the material after block 108 is provided as illustrated in FIG. 29.

In an embodiment, no anneal of the dielectric material following deposition is required. Further, the dielectric material may be formed with sufficient quality (e.g., dielectric performance) and/or consistency (e.g., without seams) benefiting device performance and/or providing following processes (e.g., removal of portions of the dielectric material such as by etchback or planarization) of higher control. That is, in an embodiment, a process removing a thickness of the dielectric layer, such as an etchback process of the dielectric material or a chemical mechanical polish (CMP) of the dielectric material, is performed without an anneal or other high temperature process directed to the dielectric material. In an embodiment, a process of thinning the dielectric material is performed without a further densification process on the dielectric material beyond the MW plasma treatment.

The method 100 is now described with respect to various embodiments in forming a semiconductor device such as implementing the method 100 during the formation of a CFET device. Specifically, in a first exemplary embodiment, FIGS. 2-18 illustrate an application of the method 100 to an isolation feature adjacent a vertical contact feature of a CFET device. The vertical contact feature may be an L-shaped contact feature extending from above an upper device of the CFET to a terminal (a source/drain feature) of a lower device of the CFET.

FIG. 2 illustrates a simplified fragmentary top view of the CFET device 200. For ease of reference, referring first to the top view, the device 200 includes an active region 220 extending lengthwise along the Y direction and gate structures 216 extending lengthwise along the X direction. Besides the active region 220 and the gate structures 216, the device 200 in FIG. 2 is illustrated as having contact features 208 that extend to the source/drain regions of an upper transistor of the device 200. In some implementations, the contact features 208 are referred to as MD and are part of a middle-end-of-the-line or MEOL features providing contact to the source/drain terminal of the transistor formed in the front-end-of-the-line (FEOL). Another contact illustrated is a vertical contact feature 202 and a region 204 adjacent the vertical contact feature 202. The region 204 is filled with dielectric material, which may be formed using one or more of the steps of the method 100 including for example spin-on deposition and MW plasma treatment.

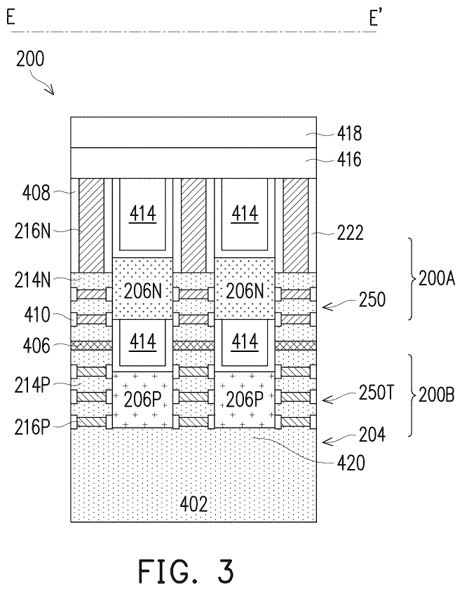

The active region may include a vertical stack of nanostructures 214 (or channel members) stacked along the Z direction. See FIG. 3. Each of the gate structures 216 includes a bottom segment 216P and a top segment 216N over the bottom segment. The top segment and the bottom segment may include different work function layer arrangement or different dipole components. In the device 200, the bottom segment 216P is a gate structure of a PMOS transistor and the top segment 216N is a gate structure of an NMOS transistor, however other arrangements are also possible. The active region includes respective source/drain regions-top source/drain region (e.g., epitaxial material doped with a dopant of a second type) 216N and bottom source/drain region (e.g., epitaxial material doped with a dopant of a second type) 216P. That is the device 200 includes a bottom transistor device 200B including gate 216P and source/drain features 206P, for example, forming a PFET, and an upper transistor device 200A including gate 216N and source/drain features 206N, for example, forming an NFET.

Transistors of a stacked transistor structure, such as stacked transistors 200A and 200B of the device 200, can be fabricated separately, monolithically, or sequentially. When fabricated separately, a top transistor and a bottom transistor may be separately fabricated, and then, the top transistor is bonded/attached to the bottom transistor. When fabricated monolithically, a top transistor and a bottom transistor are fabricated from an initial device precursor. For example, a first set of semiconductor layers may be bonded/attached to a second set of semiconductor layers and then processed to form the top transistor and the bottom transistor, respectively. When fabricated sequentially, a first set of semiconductor layers may be processed to form a bottom transistor, and then, a second set of semiconductor layers is attached/bonded to the bottom transistor and processed to form a top transistor (i.e., the top transistor is fabricated on the bottom transistor).

The device 200 also illustrates contact features. A bottom contact interfaces the source/drain feature 206P of the bottom transistor 200B. Contacts 208 interface the source/drain feature 206N of the upper transistor 200A. A metallization layer (M0) is formed over the contacts 208 and are connected by a via 210 to the contact 208. The L-shaped contact 202 extends in the illustrated embodiment to the bottom contact to provide interconnection to the source/drain feature 206P of the bottom device 200B. In some implementations, the contact to one source/drain features 206N of the upper device 200A is connected to one source/drain feature 206P of the bottom device 200B through the L-shaped contact 202. The L-shaped contact 202 includes a vertically extending portion (z-direction) and a lower, horizontally extending portion (y-direction). The region 204 is filled with dielectric material. The region 204 has dielectric material on top of the horizontally extending portion and abutting a sidewall of the vertically extending portion. In effect, filling-in the L-shape. The region 204 may be fabricated using one or more aspects of the method 100 as discussed below.

FIG. 3 illustrates a fragmentary cross-sectional view of the CFET device 200. The device 200 includes a substrate 402. The substrate 402 is similar to the substrate described above in conjunction with the method 100 of FIG. 1. Substrate 402 includes an elementary semiconductor, such as silicon and/or germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP, GaInAsP, or a combination thereof; or a combination thereof. In the depicted embodiment, substrate 402 is a silicon substrate. In some embodiments, substrate 402 is a semiconductor-on-insulator substrate, such as a silicon-on-insulator (SOI) substrate, a silicon germanium-on-insulator (SGOI) substrate, or a germanium-on-insulator (GOI) substrate. Substrate 402 can include various doped regions, such as p-type doped regions (e.g., p-wells), n-type doped regions (e.g., n-wells), or a combination thereof. N-type doped regions include n-type dopants, such as phosphorus, arsenic, other n-type dopant, or a combination thereof. P-type doped regions include p-type dopants, such as boron, indium, other p-type dopant, or a combination thereof. In some embodiments, the doped regions include a combination of p-type dopants and n-type dopants. In some embodiments, the device 200 includes a bottom silicon germanium layer over the base substrate and a bottom silicon layer is disposed over the bottom silicon germanium layer.

Channel members 214 of the active region 220 are illustrated in FIG. 3. It is noted that the number of channel members 214 for each of the transistors 200B, 200A is exemplary only and more or fewer channel members 214 may be present. In some implementations to form the channel members 214, sacrificial semiconductor layers and channel semiconductor layers (that form the channel members 214) are stacked vertically (e.g., along the z-direction) in an interleaving and/or alternating configuration from a top surface of substrate 402. A composition of sacrificial semiconductor layers is different than a composition of the channel semiconductor layers to achieve etching selectivity and/or different oxidation rates during subsequent processing. Sacrificial semiconductor layers and channel semiconductor layers include different materials, constituent atomic percentages, constituent weight percentages, thicknesses, or a combination thereof to achieve desired etching selectivity during an etching process, such as an etch process implemented to form suspended channel layers, here channel members 214, collectively and annotated 214P, 214N. In an embodiment, channel members 214 include silicon. The channel members 214 of the upper device 200A are annotated as channel members 214N and the channel members 214 of the lower device 200B are annotated as channel members 214P.

A middle dielectric isolation feature 406 is disposed between the topmost one of the bottom channel members 214P and a bottommost one of the top channel members 214N. The middle dielectric isolation feature 406 may include silicon oxide, silicon nitride, or a combination thereof.

The gate structure of the CFET 200 includes a bottom segment 216P associated with the device 200A and a top segment 216N associated with the device 200B. In some embodiments, the bottom segments 216P includes a p-type work function metal layer and the top segment 216N includes n-type work function metal layer. In some alternative embodiments, the bottom segments 216P includes an n-type work function metal layer and the top segment 216N includes a p-type work function metal layer. The gate structures 216P wraps around the bottom channel members 214P and the gate structure 216N wraps around top channel members 214N. Along the cross-section E-E′ shown in FIG. 2 that extends along the active region, the channel regions of the channel members 214 are interleaved by source/drain regions, for example, source/drain features 206P and 206N of the bottom device 200B and the top device 200A respectively. In some embodiments, the bottom source/drain features 206P include a p-type dopant and the top source/drain features 206N include an n-type dopant. In some embodiments, the bottom source/drain features 206P include silicon germanium (SiGe) and a p-type dopant and the top source/drain features 206N include silicon (Si) and an n-type dopant. A doped region (e.g., an epitaxial region) may provide isolation and be disposed below the source/drain feature 206P. A gate spacer layer 408 extends along sidewall of the gate structures 216. The gate structures 216, including the bottom segment 216P and the top segment 216N, are insulated from the bottom source/drain features 206P and top source/drain features 206N by inner spacer features 410.

An interlayer dielectric (ILD) 414 and contact etch stop layer (CESL) 412 are formed over the substrate 402. In an embodiment, the CESL 412 may include silicon nitride and the ILD layer 414 may include silicon oxide. Other example compositions of the CESL 412 include silicon carbonitride, or silicon oxycarbonitride. Other example compositions of the ILD layer 414 include, for example, silicon oxide, carbon doped silicon oxide, silicon nitride, silicon oxynitride, tetraethyl orthosilicate (TEOS)-formed oxide, boron silicate glass (BSG), phosphosilicate glass (PSG), borophosphosilicate glass (BPSG), fluorosilicate glass (FSG), Black Diamond® (Applied Materials of Santa Clara, California), xerogel, aerogel, amorphous fluorinated carbon, parylene, benzocyclobutene-based (BCB) dielectric material, SiLK (Dow Chemical, Midland, Michigan), polyimide, other suitable dielectric material, or a combination thereof. In yet another embodiment, the ILD 414 may be formed according to the method 100 including the dielectric materials deposited as discussed above with reference to block 106 and MW treatment of block 108. The ILD 414 and CESL 412 are formed for the bottom device 200B (i.e., over the bottom source/drain feature 206P) and formed for the top device 200A (i.e., over the top source/drain feature 206N).

The device 200 illustrated in FIG. 3 shows a first hard mask layer 416 is deposited over the ILD layer 414 and the gate structure 216 of the upper device 200A. A second hard mask layer 418 is disposed on the first hard mask layer 416. In some embodiments, a photoresist layer is deposited over the hard mask layers and used to pattern an opening to be etched for the device. In some embodiments, the first hard mask layer 416 includes silicon nitride and the second hard mask layer 418 includes silicon oxide. Contacts 208 may be formed through portions of ILD layer 414 and CESL 412 (not shown in FIG. 3) such as to the source/drain feature 206N.

As indicated above, in an embodiment, the ILD 414 may be fabricated according to the embodiment of the method 100 of FIG. 1. That is the ILD 414 may be deposited using blocks 106 and/or 108 of the method 100 including spin on deposition followed by MW plasma treatment using one or more of the materials discussed above, including as provided in Table 1. As illustrated below, the ILD 414 and CESL 412 are formed for both the lower device 200B and the upper device 200A of the CFET 200. Either or both of these ILD layers may be formed according to aspects of the method 100.

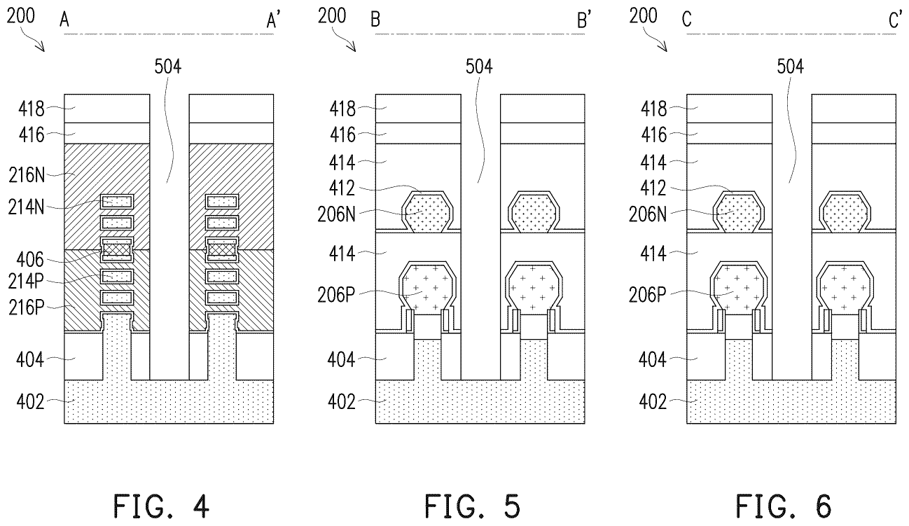

FIGS. 4-18 are now referred to illustrate the formation of the vertical contact feature 202 of the device 200 illustrated in the top view of FIG. 2. Referring to the top view of FIG. 2, a first cross-section is provided along a gate structures 216 (i.e., through the channel region) denoted A-A′ cut; a second cross-section and third cross-section are each provided along a source/drain region B-B′ and C-C′. The cut C-C′ is through a region where the contact feature is present extending to a top of the top device 200A—that is, the vertically extending portion of the contact feature 202. The cut B-B′ is through a region where the contact feature is present only adjacent a portion of the bottom device 200B—that is, the horizontally extending “leg” potion of the contact feature 202 (see FIG. 2 with region 204 above the contact feature 202 portion).

FIGS. 4, 5, and 6 each show a corresponding fragmentary cross-sectional view of the device 200 along line A-A′, B-B′ and C-C′ respectively of FIG. 2 at an interim stage of fabrication. An opening 504 is illustrated that is provided to define a region for a contact element 202 of the device 200. FIG. 5 illustrates the opening 504 extends from a top of the first device 200A through the second device 200B. The opening 504 extends through the gate structure 216 including the top segment 216N and the bottom segment 216P. The opening 504 corresponds to the contact 202 and the region 204. See FIG. 2.

As illustrated in FIG. 4, the gate structure 216 includes a gate dielectric layer formed under a gate electrode of the gate structure 216. The gate dielectric layer may include an interfacial layer and/or a high-k dielectric layer. A high-k dielectric material generally refers to dielectric materials having a dielectric constant that is greater than a dielectric constant of silicon dioxide (k≈3.9), such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TIO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃N₄, HfO₂—Al₂O₃, other high-k dielectric material, or a combination thereof.

It is noted that FIGS. 4-6 also illustrates the isolation regions between active regions. Isolation features 404 electrically isolates active device regions and/or passive device regions of a device from one another. Isolation feature 404 includes silicon oxide, silicon nitride, silicon oxynitride, other suitable isolation material (including, for example, silicon, oxygen, nitrogen, carbon, other suitable isolation constituent, etc.), or a combination thereof. Isolation feature 404 may have a multilayer structure. For example, isolation feature 404 includes a bulk dielectric (e.g., an oxide layer) over a dielectric liner (including, for example, silicon nitride, silicon oxide, silicon oxynitride, silicon oxycarbonitride, or a combination thereof). In another example, isolation feature 404 includes a dielectric layer over a doped liner, such as a boron silicate glass (BSG) liner and/or a phosphosilicate glass (PSG) liner. Dimensions and/or characteristics of isolation feature 404 are configured to provide a shallow trench isolation (STI) structure, a deep trench isolation (DTI) structure, a local oxidation of silicon (LOCOS) structure, other suitable isolation structure, or a combination thereof. In an embodiment, isolation feature 404 is an STI between portions of the substrate.

FIG. 5 and FIG. 6 each illustrate the opening 504 extending through the source/drain region of the device 200. The opening 504 extends between adjacent upper source/drain regions 206 of adjacent devices and vertically extends through the upper device 200A and the lower device 200B of the device 200. The opening 504 may be formed by suitable lithography and etching processes. In some implementations, the etching is an anisotropic etching providing the opening 504 having substantially linear sidewalls. In an embodiment, the aspect ratio of the opening 504 is greater than approximately 4:1 (depth to width). As shown in FIGS. 5 and 6, the bottom source/drain features 206 are covered by a bottom CESL 412 and a bottom ILD layer 414 and the top source/drain features 206 are covered by the top CESL 412 and the top ILD layer 414.

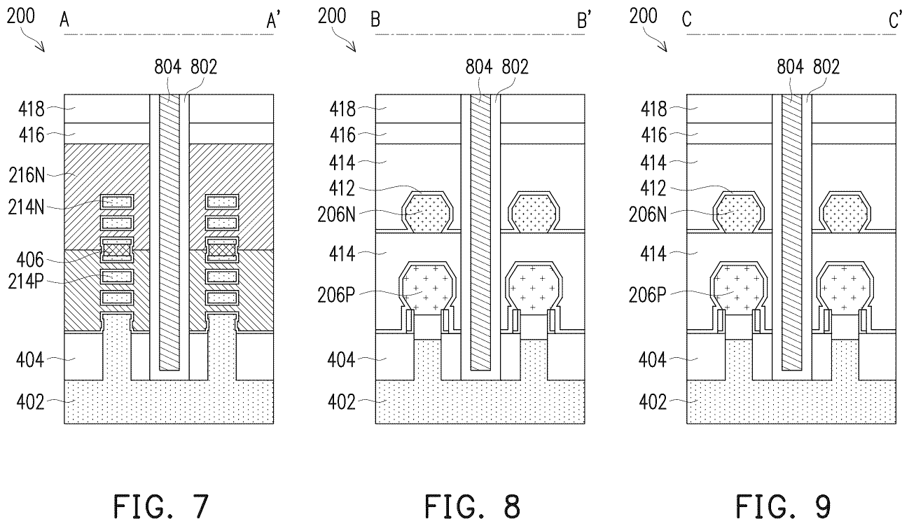

After forming the opening 504, the opening is filled with a dielectric liner layer and a conductive material over the dielectric liner layer. As illustrated in FIGS. 7, 8, and 9, a dielectric liner layer 802 is formed conformally formed on the sidewalls of the opening 504. In an embodiment, the dielectric liner layer 802 is a silicon nitride composition. A conductive material 804 is filled in the opening 504 over the dielectric liner layer 802. In an embodiment, the conductive material 804 is ruthenium (Ru). In other implementations, other conductive materials are possible such as, for example, nickel (Ni), cobalt (Co), copper (Cu), or a combination thereof. In some implementations, the deposition of the materials 802, 804 may be performed by ALD, PVD, CVD, high density plasma CVD (HDPCVD), metal organic CVD (MOCVD), remote plasma CVD (RPCVD), plasma enhanced CVD (PECVD), low-pressure CVD (LPCVD), atomic layer CVD (ALCVD), atmospheric pressure CVD (APCVD), plating, other suitable process, or a combination thereof. In an embodiment, after deposition, a planarization process such as a chemical mechanical polish (CMP) is performed to remove the deposited material from a top surface of the device. The hard mask layers 416 and 418 may also be removed as illustrated in FIGS. 7, 8, 9.

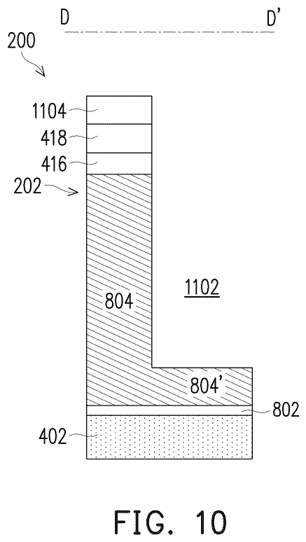

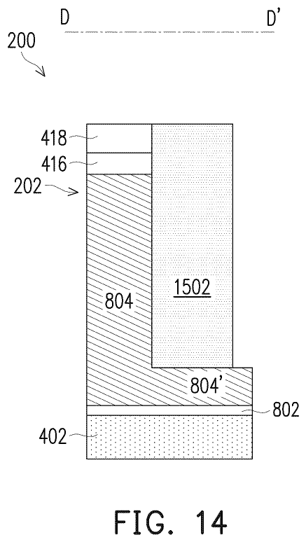

In some portions of the device 200, the conductive material is etched back. And portions of the conductive material are maintained to form a contact structure. Referring to the example of FIG. 10, the conductive material 804 is etched back to form etched back conductive material 804′ and an overlying opening 1102. FIG. 10 also illustrates a region where the conductive material 804 is maintained. The conductive material 804,804′ after patterning as illustrated in FIGS. 10, 11, 12, and 13, forms an L-shaped contact structure, illustrated as contact structure 202 in FIG. 2 discussed above. FIG. 14 illustrates that the vertical contact feature 202 includes an L shape of conductive material 804, 804′ when viewed along the cross-section of D-D′ of FIG. 2. The contact 202 is vertically spaced apart from the substrate 402 by the liner 802.

In some implementations, the etching back of the conductive material 804 and forming the opening 1102 is provided by patterning additional hard mask layer(s) 416, 418, and layer 1104. In an embodiment, layer 1104 is a hard mask material. In an embodiment, layer 1104 is a photosensitive material. The layers 416, 418, 1104 may be patterned by suitable lithography and etching processes to define openings over the respective portions of the conductive material 804.

The opening 1102 has an aspect ratio of greater than 1 (height:width) in at least one direction (e.g., C-C′ and A-A′ cross-sectional directions of FIG. 3). In an embodiment, the opening 1102 has an aspect ratio of greater than 4:1 (height:width). The opening 1102 may be defined as a region for dielectric material as discussed above with reference to block 104 of the method 100 of FIG. 1 and illustrated as region 204 of FIG. 2.

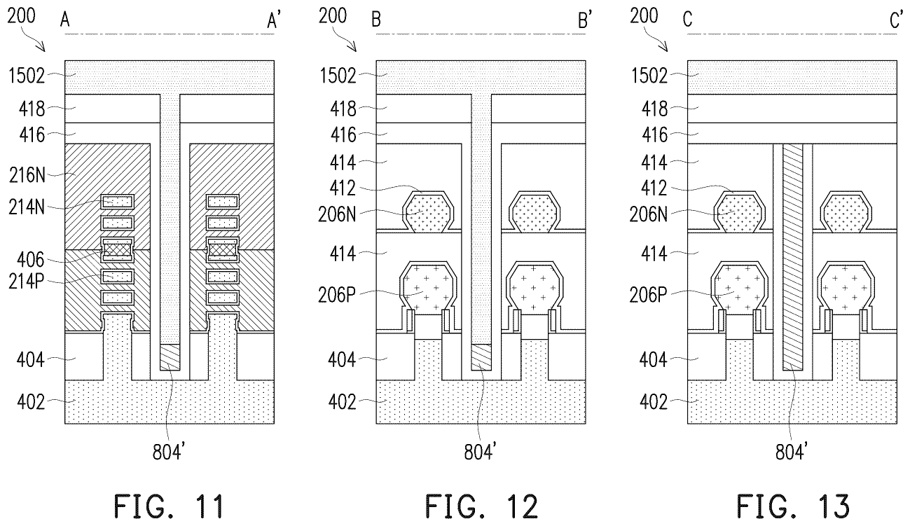

FIGS. 11, 12, 13 and 14 illustrate fragmentary cross-sectional views of the device 200 after dielectric material has then been deposited in accordance with aspects of the block 106 of the method 100 of FIG. 1. In particular, dielectric material 1502 is formed on the device 200 including within the opening 1102. FIG. 11 illustrates a fragmentary cross-sectional view of the along line A-A′ where a dielectric material 1502 is deposited over the device 200, including in the opening 1102 over etched back conductive material 804′, which provides a horizontally extending portion of the L-shaped conductive structure 202. FIG. 12 illustrates a fragmentary cross-sectional view of the along line B-B′ where a dielectric material 1502 is deposited over the device 200, including in the opening 1102 over etched back conductive material 804′, which provides a horizontally extending portion of the L-shaped conductive structure 202. FIG. 13 illustrates a fragmentary cross-sectional view of the along line C-C′ the conductive material 804 remains extending to a top surface of the device 200, providing a vertically extending portion of the L-shaped conductive structure 202.

In an embodiment, the dielectric material 1502 is deposited by spin-on deposition as discussed above with reference to block 106 of the method 100 of FIG. 1. In an embodiment, the dielectric material 1502 may be a material substantially similar to as discussed above with reference to block 106 of the method 100 of FIG. 1, including, for example, one or more compositions of the Table 1. In another embodiment, the dielectric material may be silicon oxide, a nitride such as silicon nitride, a low-k dielectric material, and/or other suitable material. A low-k dielectric material includes a material with a dielectric constant that is less than about 2.5 (i.e., an extreme low-k (ELK) dielectric material), such as porous silicon oxide, silicon carbide (SiC), carbon-doped oxide (e.g., an SiCOH-based material (having, for example, Si—CH₃ bonds)), and/or other suitable materials.

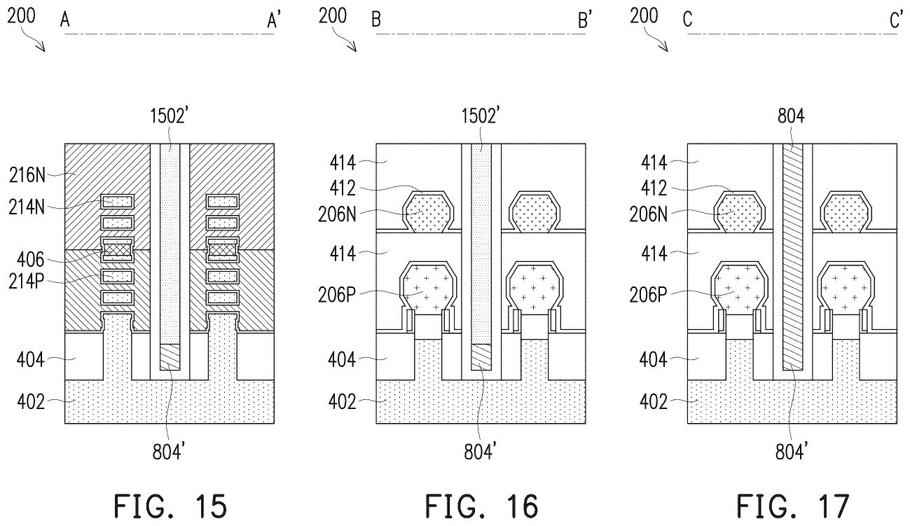

After deposition of the dielectric material, as discussed above with reference to block 108 of the method 100 of FIG. 1, a microwave plasma treatment is performed on the deposited dielectric material. The microwave plasma treatment may include reconstruction and/or densification of the dielectric material through introduction of MW plasma. FIGS. 15, 16, 17 and 18 illustrate the dielectric material 1502 has be treated resulting in treated dielectric material 1502′.

By way of the spin-on deposition and treatment of the dielectric material 1502, in an embodiment, a seam does not exist in the dielectric material 1502′ within the opening 1102. In some implementations, the treatment of the dielectric material 1502′ may be performed prior to the removal of the hard mask layers and/or planarization processes below. In other implementations, the treatment of the dielectric material 1502′ may be performed after to the removal of the hard mask layers and/or planarization processes below.

The device 200 may be further processed including providing a planarization process. In some embodiments, the device 200 is planarized using a chemical mechanical polishing (CMP). As shown in FIGS. 15, 16, 17 and 18, the planarization removes excess dielectric material 1502 (or 1502′) and any hard mask layers (e.g., 416 and 418) remaining on a top surface of the device 200. In some implementations, after planarization, a top surface of the top ILD layer 414 is exposed.

It noted that when the treated dielectric material 1502′ is formed (e.g., deposited and treated), the gate structures 216 are disposed on the device. In an embodiment, the gate structures 216 include metal. If a process such as an anneal process with a high temperature (greater than 500° C.) is performed to prepare a dielectric material, the high heat may damage the gate structures 216 in terms of threshold voltage shifting or degradation of on-state current. Because the dielectric material 1502′ is formed according to aspects of the method 100 that allow a temperature less than 400° C., the thermal budget can be lowered and damage to the gate structures 216 mitigated.

Another embodiment implementing the method 100 during the formation of a CFET device is described with reference to FIGS. 19-26. Specifically, an application of the method 100 to form dummy material when patterning a gate stack of a CFET device.

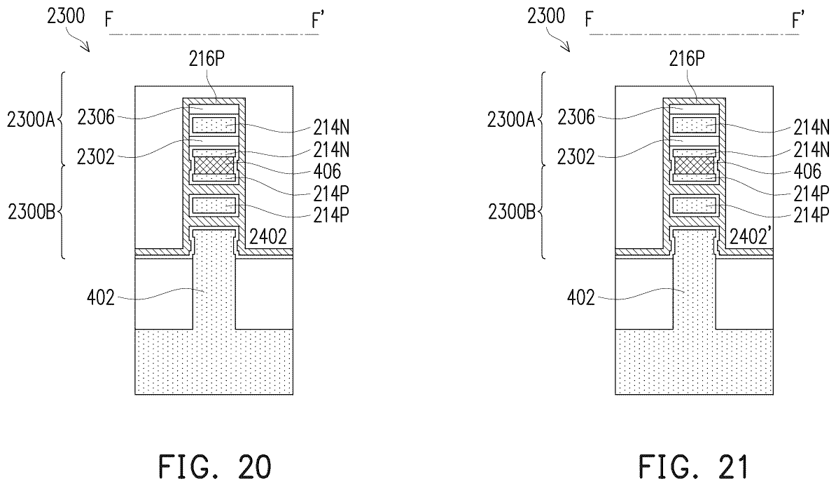

FIG. 19 illustrates a fragmentary cross-sectional view substantially similar to the view of FIG. 3. FIG. 20 illustrates an interim structure during fabrication of a CFET device 2300, in particular provided during a gate stack formation loop. A bottom device 2300B of the CFET device 2300 includes a gate structure 216P formed wrapping the channel members 214P. An isolation region 406 is disposed between the bottom device 2300B and a top device 2300A. The CFET device 2300 is substantially similar to the device 200.

In the interim stage of FIG. 20, the gate structure of the top device 2300A has yet to be formed. As such, the top device 2300A includes a dummy plug 2302 between channel members 214N. And the top device 2300A includes a hard mask layer 2306. In an embodiment, the dummy plug 2302 includes a dielectric material such as aluminum oxide. In an embodiment, the hard mask layer 2306 includes a dielectric material such as silicon nitride, silicon carbon nitride, and/or other suitable materials. The dummy plug 2302 and the hard mask layer 2306 may protect the channel members 214N of the top device 2300A during processing the gate structure 216P of the bottom device 2300B.

An opening 2304 is provided in the gate region of the upper device 2300A. In some implementations, the opening 2304 provides a region defined for dielectric material such as provided in block 104 of the method 100.

Continuing the application of the method 100 to the exemplary device 2300, in some implementations of forming the CFET 2300, at this stage of fabrication a dummy layer is deposited in the opening 2304 according to block 106 of the method 100. FIG. 20 provides a fragmentary, cross-sectional view along cut F-F′ of FIG. 19 where a dummy material 2402 has been formed in opening 2304.

In the interim device of FIG. 20, one or more layers of a metal gate may be formed on a bottom transistor surrounding the lower active layers 214P. At this stage, epitaxial source/drain features may have been formed. In some implementations, the metal gate 216P may have a work function tuned to a first device type (e.g., a p-type work function) and be overlying a gate dielectric. A dummy material 2402 is then formed over the one or more layers of the metal gate of the bottom transistor. In some implementations, the dummy material 2402 serves to protect the bottom gate features from processing (e.g., gate dielectric and gate electrode) while upper gate features are to be formed as discussed below.

In an embodiment, the dummy material 2402 is formed according to aspects of the method 100. That is, in some implementations, the dummy material 2402 is deposited in the opening 2304 according to aspects of the block 106 of the method 100 of FIG. 1. For example, in some implementations, the dummy material 2402 is deposited by spin-on deposition processes. An as another example, in an embodiment, the dummy material 2402 may include one or more dielectric materials of Table 1 discussed above.

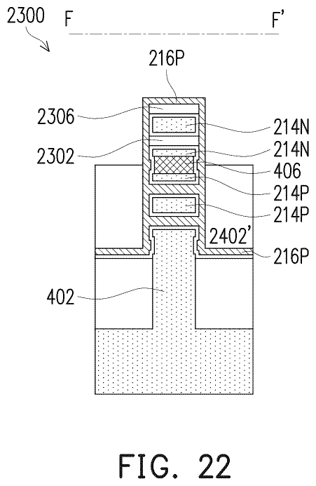

After deposition of the dummy material 2402 into the opening 2304, the dummy material may be subjected to a MW plasma treatment as discussed above with reference to block 108 of the method 100 of FIG. 1. The microwave plasma treatment may include reconstruction and/or densification of the deposited dummy material through introduction of MW plasma. FIG. 21 illustrates a MW treated dummy material 2402′. By way of the spin-on deposition and treatment of the dummy material to form treated dummy material 2402′, in an embodiment, a seam does not exist within the dummy material. Thus, during subsequent etching processes, for example, an etchback process on the dummy material 2402′ as illustrated in FIG. 22, a uniform removal of the dummy material 2402′ is provided. In an embodiment, the etching back of the dummy material 2402′ is performed at a temperature of between approximately −10° C. to approximately 250° C. In an embodiment, a reactant gas and carrier gas for the etchant (e.g., plasma etching) may include HF, NH₃, Ar, N₂, and/or other suitable gases. In an embodiment, the etchback process is performed at a pressure of between approximately 100 mTorr to approximately 3500 mTorr.

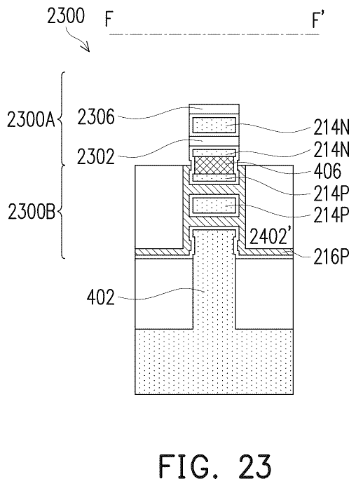

After etching back the dummy material 2402′, the exposed portions of the metal gate 216P may be removed. In some implementations, the metal gate 216P may have a work function tuned to a first device type (e.g., a p-type work function) that device type being associated with the bottom device 2300B. As a second device type (e.g., n-type work function) is desired for the top device 2300A, it desired to remove the metal gate 216P. The metal gate 216P may be removed at a temperature of between approximately 20° C. and approximately 75° C. In an embodiment, the metal gate 216P is removed by an etching process (e.g., plasma etching) that includes an etching gas of H₂O, H₂O₂, NH₄OH, and/or other suitable gases. The etching process may be a selective etching process targeting the conductive material of the metal gate 216P. FIG. 23 illustrates the metal gate 216P having been removed.

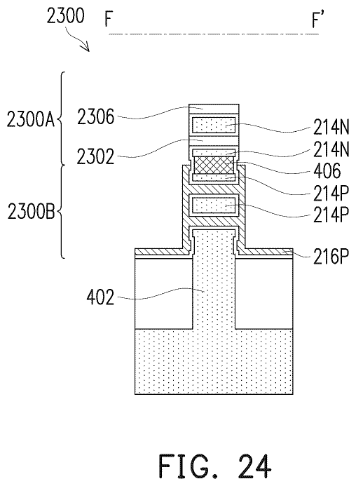

After removing the metal gate 216P, the etched back, treated dummy material 2402′ is removed from the device 2300 as illustrated in FIG. 24. In an embodiment, the removal of the dummy material 2402′ is performed at a temperature of between approximately −10° C. and approximately 250° C. In an embodiment, the dummy material 2402′ is removed by an etching process implementing reactant gases (and carrier gases) of HF, NH₃, Ar, N₂, and/or other suitable gases. In an embodiment, the dummy material 2402′ is removed at process pressure of between approximately 10 mTorr and approximately 3500 mTorr.

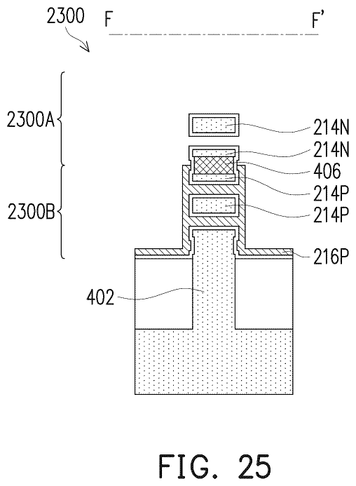

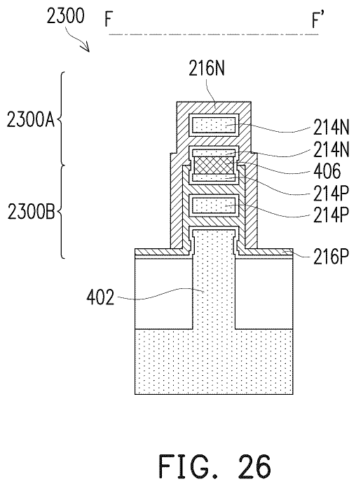

The processes of forming the CFET 2300 may continue to remove the hard mask 2306 and the dummy plug 2302 from the device 2300A as illustrated in FIG. 25. In an embodiment, the removal is performed by selective etching processes. In an embodiment, the removal is a wet etching process. After removing the hard mask 2306 and the dummy plug 2302, the upper channel members 214P are freed and have exposed surfaces. A metal gate is then deposited, as illustrated in FIG. 26, metal gate 216N is formed over the device 2300 and the channel members 214P. The metal gate 216N may provide a different work function that the metal gate 216P. In one embodiment, the first work function layer 216P is a p-type work function layer and the second work function layer 216N is an n-type work function layer. In another example, the first work function layer 216P is an n-type work function layer and the second work function layer 216N is a p-type work function layer. Example n-type work function materials include Ti, Al, Ag, Mn, Zr, TiAl, TiAlC, TaC, TaCN, TaSiN, TaAl, TaAlC, or TiAlN. Example p-type work function materials include TiN, TaN, Ru, Mo, Al, WN, ZrSi₂, MoSi₂, TaSi₂, NiSi₂, or WN. In some implementations, the metal gate 216N is substantially similar to as discussed above with reference to the device 200 including the description accompanying FIG. 3. Forming the metal gate 216N in some implementations provides for forming an interfacial layer, a gate dielectric layer such as a high-k gate dielectric and a gate electrode layer.

The processing of the device 2300 may then proceed to forming MEOL contacts, including those contact features such as the L-shaped contact 202 discussed above.

As described above, the top device of a CFET and the bottom device of a CFET have different composition requirements to affect the different performances. For that reason, they require differentiated processing. One way to provide differentiated processing is the use of dummy layers, such as the dummy material 2402 described in the embodiment of the CFET device 2300. As described in detail above, a dummy fill material 2402 is formed according to the method 100 of FIG. 1 to provide for deposition of different work function layers targeting the top device 2300A. Other uses of dummy fill layers that are deposited and patterned or etched back to cover the bottom channel members 214P or bottom device features such as source/drain regions or gate structures, while materials or treatments are performed around the top channel members 214N may also be implemented. Any or all of these dummy layers may be fabricated according to the method 100 of FIG. 1.

For another example, a dummy material may also be used forming different dipole layers. In particular, different dipole layers are introduced to top channel members (nanostructures) and bottom channel members (nanostructures) in different device regions. As above, in the fabrication of such as device, the dummy material is formed to cover the bottom channel members (e.g., 214P) and the top channel members (e.g., 214N), and then etched back to expose the top channel members (e.g., 214N). Because the dummy material is formed after some gate layers that include metal are deposited and because the dummy material is subjected to an etch back process, it is beneficial to form the dummy layer using processes that do not strain the thermal budget, or in other words are provided a relatively low temperature but are formed of uniform quality (e.g., without seams) and high density.

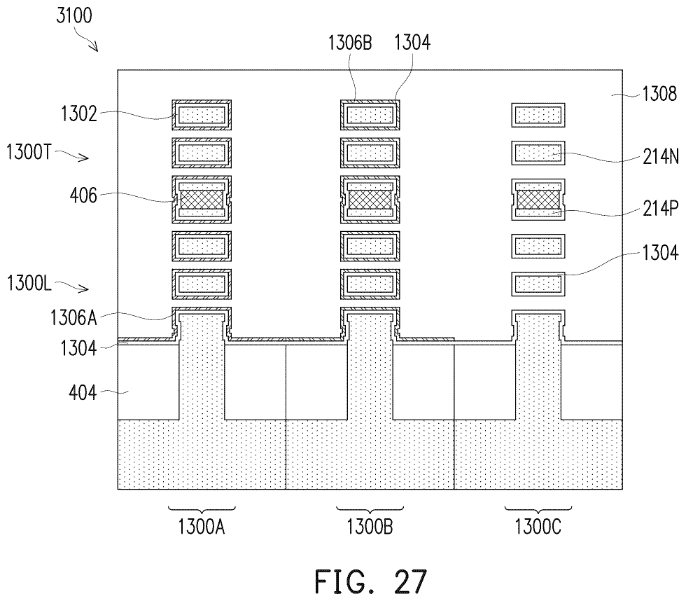

Reference is made to FIG. 27 to provide an exemplary device 3100. The device 3100 includes three device regions-a first region 1300A, a second region 1300B, and a third region 1300C. The workpiece 400 includes a substrate 402 substantially similar to as discussed above with reference to the embodiment of the device 200. For example, an isolation feature 404 is formed on the substrate 402. Like the active regions of device 200 described above, a plurality of bottom channel members 214P and a plurality of top channel members 214N are provided. A middle dielectric isolation feature 406 is disposed between the topmost one of the bottom channel members 214P and a bottommost one of the top channel members 214N.

As shown in FIG. 27, an interfacial layer 1302 is formed over surfaces of the channel members 214. In an embodiment, the interfacial layer 1302 is formed by thermal oxidation forming, for example, silicon oxide. A gate dielectric layer 1304 is then deposited over the interfacial layer 1302 and a top surface of the isolation feature 404 using CVD or ALD. The gate dielectric layer 1304 may include, for example, HfO₂, HfSiO, HfSiON, HfTaO, HfTiO, HfZrO, ZrO₂, Al₂O₃, HfO₂—Al₂O₃, TiO₂, Ta₂O₅, La₂O₃, Y₂O₃, other suitable high-k dielectric material, or combinations thereof. Over the first region 1300A, a first dipole material 1306A is conformally deposited over the gate dielectric layer 1304 using ALD or CVD. Over the second region 1300B, a second dipole material 1306B is conformally deposited over the gate dielectric layer 1304 using ALD or CVD. The first region 1300A is free of the second dipole material 1306B. The second region 1300B is free of the first dipole material 1306B. The third region 1300C is free of both the first dipole material 1306A and the second dipole material 1306B. In some embodiments, the dipole materials 1306A, 1306B are both n-type dipole materials and are different in terms of composition or thickness.

A dummy material 1308 is deposited over the first region 1300A, the second region 1300B and the third region 1300C. In an embodiment, the dummy material 1308 is formed according to aspects of the method 100 of FIG. 1. For example, in an embodiment, the dummy material 1308 is deposited according to one or more aspects of the block 106 of the method 100, for example, by spin-on coating of a dielectric material and/or comprises material(s) selected from Table 1. In a further embodiment, the dummy material 1308 is subjected to a MW plasma treatment according to aspects of block 108 of the method 100 of FIG. 1.

In certain implementations, the dummy fill material 1308 after MW plasma treatment may then be reduced in thickness, or etched back, such that processing of one or more regions of the device 3100 may be performed. In some implementations, the dummy fill material 1308 is maintained over channel members 214P of a bottom device 1300L and processing of materials over the channel members 214N of the top device 1300T are performed. For example, additional dipole materials may be selectively deposited and/or selectively removed. After providing a suitable configuration of dipole materials over the respective channel members 214P, 214N of the regions 1300A, 1300B and 1300C, a drive-in process is performed. The process may continue to fabricate the device 3100 including forming gate electrodes for the bottom device 1300L and the top device 1300T.

In one exemplary aspect, the present disclosure is directed to a method. The method comprises providing a semiconductor substrate, depositing a dielectric material over the semiconductor structure, treating the dielectric material with a microwave (MW) plasma, and after the treating, removing a portion of the treated dielectric material.

In an embodiment of the method, depositing the dielectric material is by a spin-coating process. In some implementations, depositing the dielectric material includes introducing at least one compound of the following compounds to the semiconductor structure:

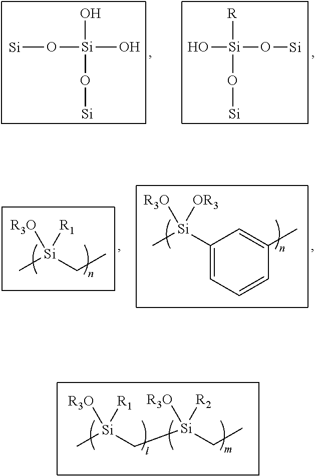

and wherein R, R1, R2, R3 are each an alkyl series and each of n, 1 and m are greater than 0. In an embodiment, the introduced compound is

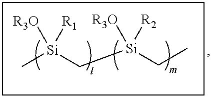

and wherein a ratio of 1 to m is between approximately 0.05 and approximately 0.95. In a further embodiment, the introduced compound is

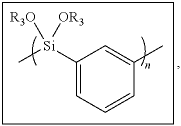

and n is between approximately 10 and approximately 20. And in an embodiment, the dielectric material becomes at least one of silicon oxide or silicon carbon oxide. In an embodiment of the method, the treating the dielectric material is performed at a temperature of less than 500° C. In some implementations, depositing the dielectric material includes forming the dielectric material in an opening having a depth to width aspect ratio greater than 1.

In one exemplary aspect, a method is provided comprising receiving a device that includes at least one on metal feature disposed on a substrate and forming a trench over the substrate, wherein the trench has a depth to width aspect ratio greater than 1. A spin-on deposition process is used to provide a dielectric material over the substrate and within the trench. The method continues to include performing a microwave (MW) treatment of the dielectric material.

In a further embodiment, wherein the spin-on deposition process includes introducing at least one compound of the following compounds to the substrate:

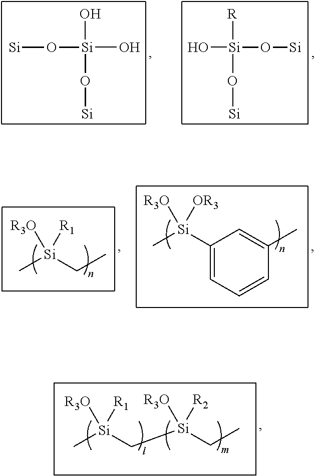

and wherein R, R1, R2, R3 are each an alkyl series and each of n, 1 and m are greater than 0. In some implementations, the treatment is performed on the dielectric material is performed on a silicon oxide or silicon carbon oxide material resulting from the at least one compound (e.g., previously listed).

In an embodiment, the spin-on deposition process fills the trench disposed over and adjacent a contact feature and the contact feature has an L-shape in a first cross-sectional view. In an embodiment, at least one metal feature is a metal gate structure surrounding a channel region of a first transistor. In some implementations, the at least one metal feature includes another metal feature of an L-shaped contact feature extending to a source/drain region of the first transistor.

In another exemplary aspect, a method is provided that includes forming a first transistor of a transistor stack on a substrate. A second transistor of the transistor stack is formed over the first transistor. An opening extending through a dielectric layer disposed on the substrate is etched. And the opening extends vertically adjacent the first transistor and the second transistor. The opening is filled with a conductive material. And the conductive material is etched back to form another opening. Spin-on deposition is implemented to fill the another opening with a dielectric material. And the dielectric material is treated with a microwave plasma treatment.

In some implementations, the method further includes etching back the conductive material leaving an L-shaped conductive feature in at least one cross-sectional view. The first transistor includes a gate structure extending in a first direction in a top view. In an embodiment, the treated dielectric material is disposed on a bottom region of the L-shaped conductive feature and interfaces a sidewall of a vertically extending region of the L-shaped conductive feature. The method may include the spin-on deposition providing the dielectric material of at least one of the following compounds onto the substrate:

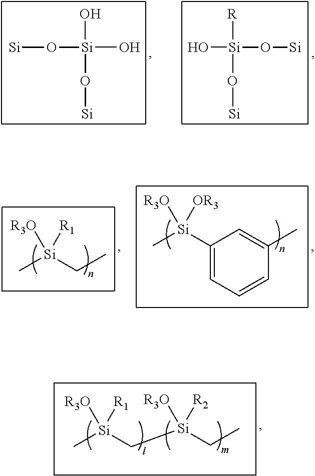

and wherein R, R1, R2, R3 are each an alkyl series and each of n, 1 and m are greater than 0.

In an embodiment, the deposition and the microwave plasma treatment are performed at a temperature of less than 500° C. In an embodiment, the microwave plasma treatment is performed with a radiation frequency centered at approximately 2.45 GHz.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a gate structure;
providing an opening extending through a plurality of dielectric layers and adjacent the gate structure;
filling a first portion of the opening with a conductive material to form a contact;
depositing a dielectric material over the conductive material in a second portion of the opening; and
treating the dielectric material with a microwave (MW) plasma.

2. The method of claim 1, wherein the depositing the dielectric material is by a spin-coating process.

3. The method of claim 1, further comprising:
forming a dielectric liner layer on sidewalls of the opening prior to filling the first portion of the opening with the conductive material.

4. The method of claim 1, further comprising:
depositing the conductive material filling the opening; and
etching back the conductive material to the first portion of the opening.

5. The method of claim 1, further comprising:
forming a shallow trench isolation (STI) feature below the gate structure.

6. The method of claim 5, wherein the providing the opening includes etching the opening into the STI feature.

7. The method of claim 1, further comprising:
forming a source/drain material with the plurality of dielectric layers.

8. The method of claim 7, wherein filling the first portion of the opening with the conductive material to form the contact forms an upper surface of the conductive material in a first cross-sectional view that is below the source/drain material.

9. The method of claim 8, wherein the conductive material in a second cross-sectional view is approximately an L-shape.

10. The method of claim 1, wherein the depositing the dielectric material includes introducing at least one compound of the following compounds: 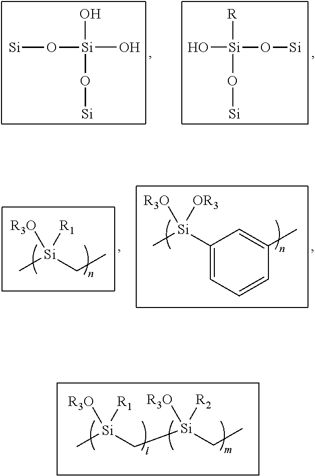
and wherein R, R1, R2, R3 are each an alkyl series and each of n, 1 and m are greater than 0.

11. A method, comprising:
receiving a device that includes a gate structure;
forming a trench extending adjacent the gate structure, wherein the trench has a depth to width aspect ratio greater than 1;
depositing a dielectric liner layer lining sidewalls of the trench between the trench and the gate structure;
using a spin-on deposition process to provide a dielectric material within the trench on the dielectric liner layer and over the gate structure; and
performing a microwave (MW) treatment of the dielectric material.

12. The method of claim 11, further comprising:
depositing conductive material into a portion of the trench prior to using the spin-on deposition process to provide the dielectric material.

13. The method of claim 11, wherein the spin-on deposition process includes introducing at least one compound of the following compounds: 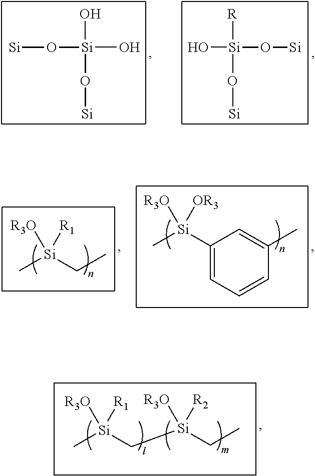
and wherein R, R1, R2, R3 are each an alkyl series and each of n, 1 and m are greater than 0.

14. The method of claim 11, wherein the depositing the dielectric liner layer includes depositing the dielectric liner layer on a bottommost surface of the trench.

15. A method, comprising:
forming a first gate of a first transistor;
forming a second gate of a second transistor, wherein the second transistor is disposed over the first transistor;
etching an opening extending through a dielectric layer disposed adjacent the first gate and the second gate;
filling an L-shape region of the opening with a conductive material, wherein a remaining portion of the opening is disposed along the L-shape region;
using spin-on deposition to fill the remaining portion of the opening with a dielectric material; and
treating the dielectric material with a microwave plasma treatment.

16. The method of claim 15, wherein the L-shape region is provided in a first cross-sectional view in a first direction, wherein the first gate and the second gate extend in a second direction different than the first direction in a top view.

17. The method of claim 16, wherein the conductive material forms an rectangular shape in a second cross-sectional view in the second direction.

18. The method of claim 15, wherein the spin-on deposition provides the dielectric material of at least one of the following compounds: 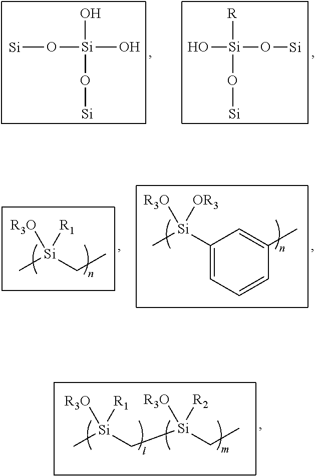
and wherein R, R1, R2, R3 are each an alkyl series and each of n, 1 and m are greater than 0.

19. The method of claim 18, wherein deposition and the microwave plasma treatment are performed at a temperature of less than 500° C.

20. The method of claim 15, wherein the microwave plasma treatment is performed with a radiation frequency centered at approximately 2.45 GHz.
